(19) United States
(12) Patent Application Publication
(10) Pub. No.: US 2008/0194109 A1
(43) Pub. Date: Aug. 14, 2008

(54) Method of fabricating a semiconductor device

(75) Inventors: Takeo Ishibashi, Tokyo (JP); Kazumasa Yonekura, Tokyo (JP); Masaaki Shinohara, Tokyo (JP); Mamoru Terai, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/071,014

(22) Filed: Feb. 14, 2008

(30) Foreign Application Priority Data
Feb. 14, 2007 (JP) 2007-033779
Jan. 25, 2008 (JP) 2008-015535

(51) Int. Cl. H01L 21/311

(52) U.S. Cl. 438/703; 257/E21.249

(57) ABSTRACT

A method of fabricating a semiconductor device includes the steps of: depositing on a main surface of a semiconductor substrate a layer to be processed; depositing a base layer on the layer to be processed; depositing a first intermediate layer and then a second intermediate layer on the base layer; patterning the second intermediate layer while the base layer covers the layer to be processed; depositing a first mask pattern on the patterned second intermediate layer; patterning the second intermediate layer with the first mask pattern; patterning the first intermediate layer and the base layer with the patterned second intermediate layer to form a second mask pattern; and patterning the layer to be processed, with the second mask pattern.

### BACKGROUND OF THE INVENTION

1. Field of the Invention

The present invention relates generally to methods of fabricating semiconductor devices, and particularly to methods of fabricating semiconductor devices having a pattern of a fine pitch formed by combining lithography performed at least twice.

2. Description of the Background Art

In recent years, forming fine semiconductor circuit patterns depends greatly on advance of photolithography technology, and it has been brought mainly by employing sources of light having shorter wavelengths for exposure.

However, simply not only are exposure systems of shorter wavelengths costly, a variety of technological issues themselves associated with devices, materials, masks and the like that short-wavelength lithography technology requires is also significantly difficult to resolve. Accordingly, employing a method other than using shorter wavelengths to provide fine patterns is being studied in various quarters.

Furthermore, fabricating a 32 nm node device requires a level in resolution corresponding to the level of immersion lithography with an NA in a vicinity of up to 1.6 that employs a liquid of a high index of refraction or the level of EUV exposure technology of 13.5 nm in wavelength. However, it is pointed out that such techniques are currently insufficiently completed, and their developments may not catch up with commercial needs.

Under such circumstances, since around the year of 2005, M. Maenhoudt, J. Versluijs, H. Struyf. J. Van Olmen, M. Van Hove, “Double Patterning Scheme for Sub-0.25 k1 Single Damascene Structures at NA=0.75, λ=193 nm” Proc. of SPIE Vol. 5754, P1508-1518 (2005) presented in an academy a method that implements a pattern pitch that is below the optical principle by combining lithography performed twice. Thereafter, methods employing lithography performed twice have increasingly been studied.

In the year of 2006, providing a flash memory with a fine pitch by combining lithography performed twice was studied by Hynix Semiconductor Inc., as described in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006), and similarly, Hynix Semiconductor Inc. has reported a low cost process flow employing Si-containing BARC to eliminate a dry etching step, as described in Sungkoo Lee, Jaechang Jung, SungyoonCho et al., “Double exposure technology using silicon containing materials” Proc. of SPIE vol. 6153, 61531K-P1-7 (2006).

Furthermore, semiconductor device fabrication includes a large number of steps of processing a silicon oxide film, a silicon nitride film and other similar insulation films, polysilicon, tungsten silicide, aluminum and other similar electrically conductive films, and other various films deposited on a semiconductor substrate.

Device fabrication of a design rule of 65 nm-45 nm involves fine processing employing ArF resist poor in anti dry etchability. Accordingly, these layers to be processed are processed as follows: for example, a resist layer is deposited on a layer to be processed, and is exposed to light and developed to form a resist pattern, which is in turn used as an etching mask in dry etching to process the layer to be processed.

In doing so, when the resist film is exposed to light, a level of resolution, a margin of an amount of exposure to light or a focus margin, as desired, should be ensured, and to do so, the resist should be reduced in thickness. However, if the resist is excessively reduced in thickness, then while the layer to be processed is being dry etched the resist pattern is completely etched away and the layer to be processed would no further be processed. To overcome this problem, a multilayer resist method is adopted. More specifically, a pattern transfer material is applied on the layer to be processed and subsequently resist is applied and a resist pattern is transferred on the pattern transfer material, and the layer to be processed is dry etched.

Rayleigh's equation representing optical resolution power is represented below as expression (1):

R=k1·(λ/NA) (1),

wherein

R: pattern resolution,

λ: wavelength of light for exposure,

NA: numerical aperture of lens, and

k1: process factor.

Herein, a pattern which is fine and has a repeated pitch with a process factor k1 below 0.25 cannot be resolved on a physical, optical principle even under an ideal optical condition employing a perfect phase shift mask and completely coherent illumination, as first order diffracted light does not enter the lens's NA (or pupil) on optical principle.

Accordingly, the pattern that is fine and has a repeated pitch with a process factor k1 below 0.25 is formed by a method employing two processes. More specifically, a pattern of twice a pitch is formed and thereafter between such formed patterns a further pattern is formed.

Thus combining two patterns appears to be easy when it is seen as combining graphics. In reality, however, using a photoresist pattern as a mask to etch a layer to be processed that is used for a variety of semiconductor fabrications to transfer a pattern to the layer invites a significantly complicated process.

If providing a layer to be processed with a combined pattern is simply considered, performing lithography and etching twice repeatedly to do so is expected, which would require an at least doubled process cost.

### SUMMARY OF THE INVENTION

The present invention has been made to overcome the above described disadvantages and it contemplates a method of fabricating a semiconductor device that is capable of forming a fine pattern while minimizing its process cost.

The present method of fabricating a semiconductor device in one aspect includes the steps of: depositing on a main surface of a semiconductor substrate a layer to be processed; depositing a base layer on the layer to be processed; depositing a first intermediate layer and then a second intermediate layer on the base layer; patterning the second intermediate layer while the base layer covers the layer to be processed; depositing a first mask pattern on the patterned second intermediate layer; patterning the second intermediate layer with the first mask pattern; patterning the first intermediate layer and the base layer with the patterned second intermediate layer to form a second mask pattern; and patterning the layer to be processed, with the second mask pattern.

The present method of fabricating a semiconductor device in another aspect includes the steps of: depositing on a main surface of a semiconductor substrate a layer to be processed; depositing a base layer on the layer to be processed; depositing a first intermediate layer and then a second intermediate layer on the base layer; patterning the second intermediate layer while the base layer covers the layer to be processed; depositing a first mask pattern on the first intermediate layer located adjacent to a gap of the patterned second intermediate layer; patterning the first intermediate layer with the first mask pattern and the patterned second intermediate layer; patterning the base layer with the patterned first intermediate layer to form a second mask pattern; and patterning the layer to be processed, with the second mask pattern.

The present method of fabricating a semiconductor device in still another aspect includes the steps of depositing on a main surface of a semiconductor substrate a layer to be processed; depositing a base layer on an upper surface of the layer to be processed; depositing a plurality of intermediate layers stacked on an upper surface of the base layer; patterning the intermediate layers more than once to form a stack of patterned layers; and etching the base layer and the layer to be processed, with the stack of patterned layers used as a mask.

The present method of fabricating a semiconductor device can thus provide a fine pattern while minimizing its process cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1-9 are cross sections for illustrating first to ninth steps, respectively, of a process for fabricating a semiconductor device in a first embodiment.

FIGS. 10-16 are cross sections for illustrating first to seventh steps, respectively, of a process for fabricating a semiconductor device in a second embodiment.

FIG. 17 is a cross section for illustrating a step performed after the process for fabricating the semiconductor device shown in FIG. 15.

FIG. 18 is a cross section for illustrating a step performed after that shown in FIG. 17.

FIG. 19 is a cross section for illustrating a first step of a process for fabricating a semiconductor device in a second exemplary variation.

FIGS. 20-26 are cross sections for illustrating steps performed after those of the process shown in FIGS. 19-25, respectively.

FIG. 27 is a cross section for illustrating a step performed after that shown in FIG. 26.

FIGS. 28 and 29 are plan views in the fourth and seventh steps, respectively, of the process for fabricating the semiconductor device in the first embodiment.

FIGS. 30 and 31 are plan views in the fourth and seventh steps, respectively, as performed when the process for fabricating the semiconductor device in the first embodiment is applied to a double hole system.

FIGS. 32 and 33 are plan views in the fourth and sixth steps, respectively, for the semiconductor device in the second embodiment.

### DESCRIPTION OF THE PREFERRED EMBODIMENTS

### First Embodiment

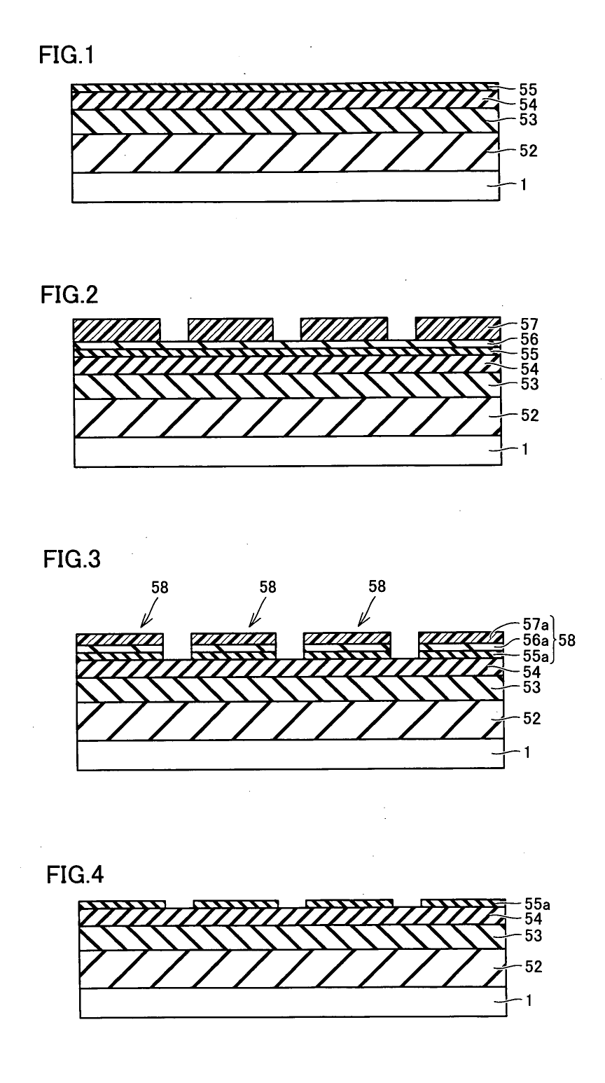

FIGS. 1-10 are used to describe a method of fabricating a semiconductor device in the present embodiment. Identical or corresponding components are identically denoted and will not be described repeatedly. FIG. 1 is a cross section for illustrating a first step of a process for fabricating a semiconductor device in the present embodiment. In FIG. 1, on a main surface of a semiconductor substrate 1a polysilicon film or a similar layer to be processed 52 is deposited. (The step of depositing a layer to be processed ends.)

On an upper surface of the layer to be processed 52, a base layer 53 is deposited. Base layer 53 is configured for example of amorphous carbon that can be deposited by chemical vapor deposition (CVD), a polymer containing an aromatic ring of a phenyl group, a naphthyl group or the like that can be deposited by spin-coating, or the like. Note that if base layer 53 is deposited by chemical vapor deposition, a film deposited on an upper surface of base layer 53 can also be deposited by chemical vapor deposition satisfactorily. If base layer 53 is deposited by spin-coating, a film deposited on base layer 53 can be deposited by spin-coating satisfactorily.

If base layer 53 is configured of amorphous carbon, then, a diode parallel plate plasma enhanced CVD system or a high density plasma chemical vapor deposition (HDP CVD) system is employed and plasma chemical vapor deposition is performed to deposit an amorphous carbon film.

A source of carbon is obtained from hydrocarbon gas, which is selected from methane (CH₄), ethane (C₂H₆), propane (C₃H₈), butane (C₄H₁₀), acetylene (C₂H₂), propylene (C₃H₆), propyne (C₃H₄) and an organic material of dimethylformaldehyde (HCON(CH₃)₂).

The hydrocarbon gas is introduced into a chamber together with at least one of helium (He), argon (Ar), nitrogen (N₂) and a similar carrier (mixture) gas. Then, in a range of 300° C. to 550° C. and at a pressure of at most 10 Torr, plasma chemical vapor deposition is employed to deposit an amorphous carbon film (α-c) to have a thickness of approximately 300 nm.

Thus on the upper surface of the layer to be processed 52 base layer 53 is provided that is formed of amorphous carbon deposited by plasma chemical vapor deposition and having a carbon content of at least 90% by weight. (The step of depositing a base layer ends.)

On base layer 53 thus deposited by chemical vapor deposition a first intermediate layer 54 is deposited. The first intermediate layer 54 can be deposited for example by chemical vapor deposition for example of plasma silicon oxide film.

If the first intermediate layer 54 is configured of plasma silicon oxide film, then a diode parallel plate plasma enhanced CVD system or an HDP CVD system is employed and monosilane (SiH₄), disilane (Si₂H₆), trimethylsilane (Si(CH₃)₄), TEOS gas (Si(OC₂H₅)₄) or a similar source gas of silane and O₂ gas, O₃ gas, CO gas or a similar oxide gas are employed to deposit the film by plasma chemical vapor deposition. The plasma silicon oxide film (P—SiO) is thus deposited for example to have a thickness of approximately 30 nm. (The step of depositing a first intermediate layer ends.)

Then on the first intermediate layer 54 deposited by chemical vapor deposition a second intermediate layer 55 is deposited that can be deposited for example by chemical vapor deposition for example of plasma silicon nitride film. For example, if the second intermediate layer 55 is configured of plasma silicon nitride film, then a diode parallel plate plasma enhanced CVD system or an HDP CVD system is used and monosilane (SiH₄), disilane (Si₂H₆), trimethylsilane (Si(CH₃)₄), TEOS gas (Si(OC₂H₅)₄) or a similar source gas of silane and N₂O gas, NH₃ gas or a similar nitride gas are employed to deposit the film by plasma chemical vapor deposition. The plasma silicon nitride film (P—SiN) is thus deposited for example to have a thickness of approximately 20 nm.

Herein, an etching selectivity of the second intermediate layer 55 relative to the first intermediate layer 54 with reference to the first intermediate layer 54 and that of the first intermediate layer 54 relative to the second intermediate layer 55 with reference to the second intermediate layer 55 both assume an etching selectivity for example of at least two.

Depositing on base layer 53 the first and second intermediate layers 54 and 55 mutually having large etching selectivity allows the second intermediate layer 55 to be patterned with the first intermediate layer 54 serving as a film protecting base layer 53, and also allows the second intermediate layer 55 to be formed to be thin. (The step of depositing a second intermediate layer ends.)

Thus on the upper surface of the layer to be processed 52 are deposited base layer 53 covering the upper surface of the layer to be processed 52 and a stack of intermediate layers deposited on base layer 53 and having the first and second intermediate layers 54 and 55.

If the stack of layers of amorphous carbon, plasma silicon oxide film and plasma silicon nitride film (P—SiN (approximately 20 nm)/P—SiO (approximately 30 nm)/α-C (approximately 300 nm)) makes it difficult to control reflectance or if resist deposited on the stack of layers and a surface of the substrate chemically react with each other to cause a pattern to flare, then the stack of layers may underlie an anti reflection layer 56. Anti reflection layer 56 can for example be a commercially available, first minimum organic anti reflective coating (ARC) produced by Nissan Chemical Industries Ltd. as ARC 83 or the like and applied to have a thickness for example of approximately 40 nm.

On an upper surface of anti reflection layer 56, an ArF photosensitive, chemically amplified resist is applied, and subsequently, a post applied bake (PAB) step of approximately 100° C. is performed to deposit a resist layer (a first resist layer).

FIG. 2 is a cross section for illustrating a second step of the process for fabricating the semiconductor device. Then, a mask is used to expose the resist layer to light. This mask is a mask described for example in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006). It is a mask having a space of a minimum width (for example of 32 nm) and a line having a width of 3 times the minimum width (i.e., of 96 nm) for configuring a portion of a circuit pattern. This mask is used to expose the resist layer to light.

After the exposure, the intermediate product undergoes a heat treatment of approximately 100° C. to 140° C. for approximately one minute, developed for approximately 30 seconds to one minute with a solution of 2.38 wt % of tetra ammonium hydroxide (TMAH), and thereafter baked at approximately 110° C. for approximately one minute to provide a resist pattern 57. In doing so, the resist layer may have an upper layer coated with such an on-resist top coating as described in Japanese Patent Laying-Open Nos. 2006-267521 and 2006-227632, as required. (The step of forming a first resist pattern ends.)

FIG. 3 is a cross section for illustrating a third step of the process for fabricating the semiconductor device. As shown in FIG. 3, resist pattern 57 is used to pattern the second intermediate layer 55 to transfer the pattern of resist pattern 57 to the second intermediate layer 55 to form an intermediate layer pattern 55a. Note that intermediate layer 55 is etched with a fluorocarbon gas obtained from CF₄, CHF₃, CH₂F₂, CH₃F or such fluorocarbon gases mixed together. An alignment mark to optically read a wafer's position is arranged to precisely register a mask described later. (The step of forming a second intermediate layer pattern ends.)

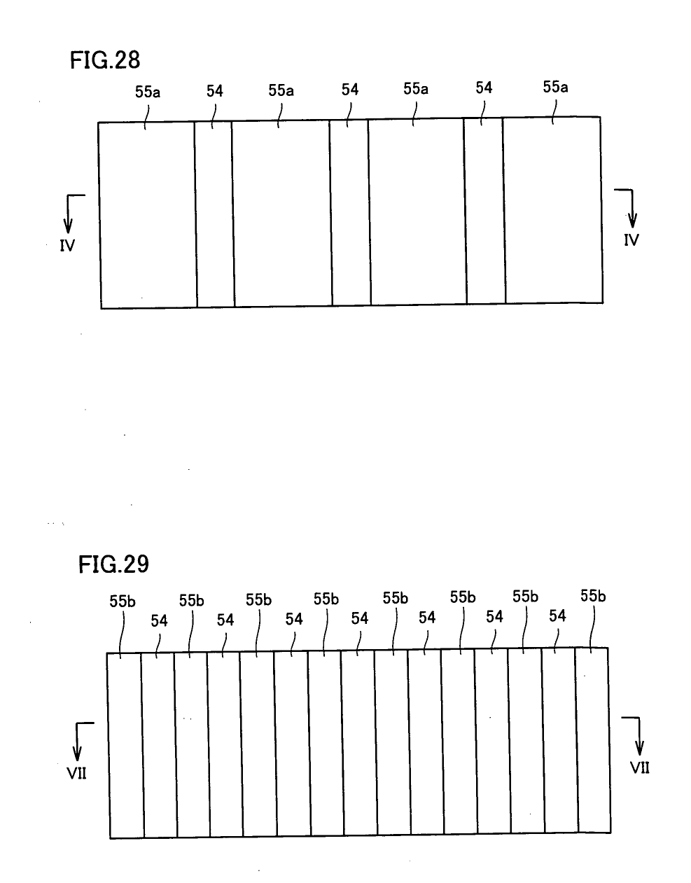

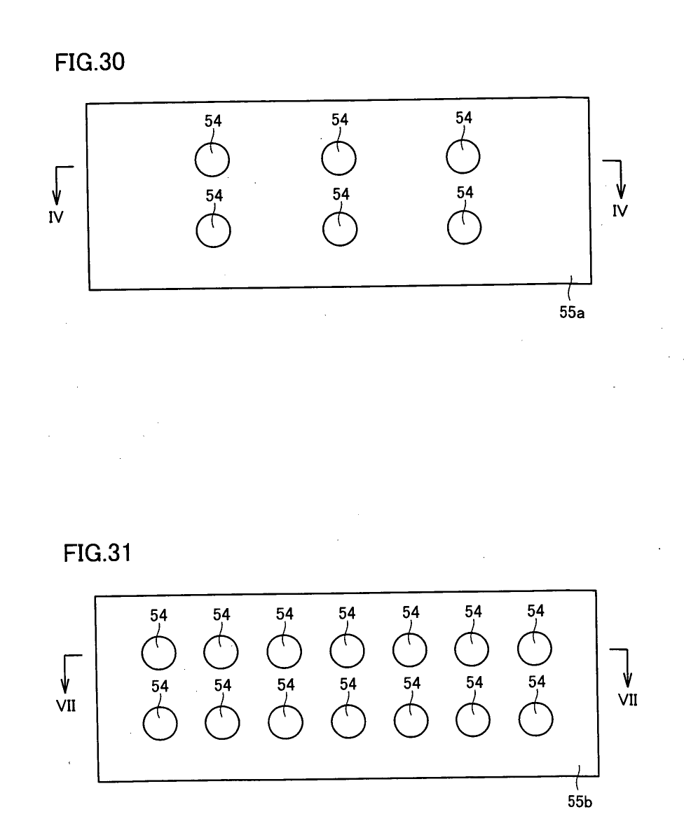

FIG. 4 is a cross section for illustrating a fourth step of the process for fabricating the semiconductor device and FIG. 28 is a plan view in the fourth step. As shown in FIGS. 4 and 28, after intermediate layer pattern 55a is formed, an O₂ plasma process is performed to ash away resist pattern 57a and anti reflection layer 56a. Wet resist peeling with sulfuric acid and hydrogen peroxide or the like may also be employed together, as required. Note that while FIG. 28 shows an example applied to a double trench system, it is not limited thereto. FIG. 30 is a plan view in the fourth step as applied to a double hole system. The method of fabricating the semiconductor device in the first embodiment can thus be applied to the double trench system and the double hole system.

FIG. 5 is a cross section for illustrating a fifth step of the process for fabricating the semiconductor device. As shown in FIG. 5, a resist layer (a second resist layer) is deposited on intermediate layer pattern 55a.

In depositing the resist layer, before the resist layer is deposited an anti reflection layer 60 may be deposited, as required.

Anti reflection layer 60 is deposited for example by applying a commercially available organic ARC produced by Nissan Chemical Industries, Ltd. as a second minimum organic ARC, i.e., ARC 29, to have a thickness of approximately 80 nm.

Such anti reflection layer 60 can fill a step that is formed in intermediate layer pattern 55a to provide a flat surface, and anti reflection layer 60 has a generally flat upper surface.

Note that intermediate layer pattern 55a is formed of plasma silicon nitride film (P—SiN) and adapted to have a thickness of approximately 20 nm. Accordingly, when anti reflection layer 60 is deposited, it can be prevented from having a large inclination over an end of intermediate layer pattern 55a. Furthermore, anti reflection layer 60 can also be prevented from having a thin portion. On an upper surface of anti reflection layer 60, a resist layer is deposited. As anti reflection layer 60 does not have an upper surface having a large inclination over the end of intermediate layer pattern 55a, the resist layer deposited on the upper surface of anti reflection layer 60 can be prevented from having a significantly inclined portion.

This resist layer (or the second resist layer) is deposited by applying an ArF photosensitive, chemically amplified resist and performing a PAB step of approximately 100° C. After the resist layer is thus deposited, a projection aligner is employed to perform an exposure step with a mask (a second mask).

This mask is a mask (the second mask) of required circuit patterns that is configured of a space of a minimum width (for example of 32 nm) and a line of a width of 3 times the minimum width (i.e., of 96 nm), as described in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006), and divided for exposure to light for a double trench structure.

In arranging this mask, it is necessary to arrange the mask, which overlies intermediate layer pattern 55a, to have a positional relationship with intermediate layer pattern 55a at a precision for example of approximately a few nm.

Herein, an alignment mark is exposed to broadband light and a method is employed to detect the mark's position by a charge coupled device (CCD) or a similar imaging device to confirm the position with high precision and thus project light for exposure thereto.

Herein, the first intermediate layer 54 is adapted to be plasma silicon oxide film and has an upper surface underlying intermediate layer pattern 55a adapted to be plasma silicon nitride film. This can help to achieve optical contrast more readily than a case with a plasma silicon layer located at an upper surface, and the alignment mark's position can be more readily detected. The mask (the second mask) can thus be registered with high precision.

When the mask is arranged and the exposure step is performed, the resist layer that does not have a significantly inclined portion and is thus generally flat can minimize or prevent defocusing. Furthermore, the resist layer does not have unsatisfactory thickness, and unsatisfactory resolution can be minimized or prevented.

After the intermediate product is thus exposed to light, it undergoes a heat treatment at approximately 100° C. to 140° C. for approximately 1 minute. Thereafter, it is developed for approximately 30 seconds to one minute with a solution of 2.38 wt % of tetra ammonium hydroxide (TMAH), and thereafter baked at approximately 110° C. for approximately one minute to provide a resist pattern 61 (a second resist pattern). Between such resist patterns 61 is located a gap 161, which overlies intermediate layer pattern 55a. (The step of forming a second resist pattern ends.)

Note that when the resist layer is patterned, the resist layer may have an upper surface coated with such an on-resist top coating as described for example in Japanese Patent Laying-Open Nos. 2006-267521 and 2006-227632, as required.

FIG. 6 is a cross section for illustrating a sixth step of the process for fabricating the semiconductor device. As shown in FIG. 6, resist pattern 61 formed as described above is used as a mask to pattern intermediate layer pattern 55a to transfer a pattern that is formed in resist pattern 61 to intermediate layer pattern 55a to form an intermediate layer pattern (or a second intermediate layer pattern) 55b.

Note that as described above, resist pattern 61 has gap 161 over intermediate layer pattern 55a, and patterning as described above patterns intermediate layer pattern 55b to be finer than intermediate layer pattern 55a.

The first intermediate layer 54 has a function protecting base layer 53, and when intermediate layer patterns 55b and 55a are formed, base layer 53 can be prevented from being etched away. Base layer 53 can thus be maintained to cover the upper surface of the layer to be processed 52. (The step of forming a second intermediate layer pattern ends.)

FIG. 7 is a cross section for illustrating a seventh step of the process for fabricating the semiconductor device. FIG. 29 is a plan view in the seventh step. As shown in FIGS. 7 and 29, an O₂ plasma process is performed to remove resist pattern 61 and anti reflection layer 60a. Wet resist peeling with sulfuric acid and hydrogen peroxide or the like may also be employed together, as required. Intermediate layer pattern 55b is thus externally exposed. FIG. 31 is a plan view in the seventh step as applied to the double hole system. As shown in FIG. 31, when the method of fabricating the semiconductor device in the first embodiment is applied for double hole, a plurality of hole patterns can be formed at fine intervals.

FIG. 8 is a cross section for illustrating an eighth step of the process for fabricating the semiconductor device. As shown in FIG. 8, intermediate layer pattern 55b is used as a mask to pattern intermediate layer 54 and base layer 53. This transfers a pattern to form an intermediate layer pattern 54a and a base layer pattern 53a, which configure a stack of layers of the pattern. Thus, base layer 53 can serve as a film protecting the layer to be processed 52, and finally, first and second patterns can be unified by base layer 53 and the layer to be processed 52 can thus be patterned.

Furthermore, base layer 53 can be configured of amorphous carbon or a similar carbon type film and assume an etching selectivity of at least 10, which is significantly large (as defined in claim 2), relative to a layer to be processed (such as polysilicon, silicon oxide film, silicon nitride film, SiOC film and the like) that is used for a variety of semiconductor fabrications. This can enhance versatility of etching of a layer to be processed.

FIG. 9 is a cross section for illustrating a ninth step of the process for fabricating the semiconductor device. As shown in FIG. 9, the layer to be finally processed 52 is patterned by intermediate layer pattern 54a and base layer pattern 53a.

Base layer pattern 53a has a pattern transferred from intermediate layer pattern 55b having a fine pattern. This allows the layer to be processed 52 to have a pattern 52a that is fine and has a repeated pitch with process factor k1 below 0.25.

Herein, an etching selectivity of the layer to be processed 52 relative to base layer pattern 53a with reference to base layer pattern 53a is larger than that of the second intermediate layer 55 relative to the first intermediate layer 54 and that of the first intermediate layer 54 relative to the second intermediate layer 55. The layer to be processed can thus be patterned satisfactorily.

Herein, a design can be done such that after the layer to be processed 52 has completely been etched, the first and second intermediate layers 54 and 55 spontaneously disappear and a carbon type layer remains. Furthermore, in contrast to inorganic film, base layer 53 formed of the remaining carbon type film can be selectively ashed away by oxygen plasma. On the other hand, for example if base layer 53 of the carbon type film is eliminated and the layer to be processed 52 instead underlies a hard mask of inorganic 2-layer film and is thus processed, then, finally, the inorganic film must be removed, and selectively removing it requires chemical mechanical polishing (CMP) or a similar a non-general-purpose removal technique.

Furthermore, for etching the layer to be processed 52 for example of polysilicon, silicon oxide film, silicon nitride film, SiOC film or the like by base layer pattern 53a of a carbon type layer, a large number of technological resources exist and are readily utilized.

Furthermore, base layer pattern 53a that is a carbon type layer assumes an etching selectivity of at least 10, which is significantly large, relative to the layer to be processed 52 (such as polysilicon, silicon oxide film, silicon nitride film, SiOC film or the like) used for a variety of semiconductor fabrications, and thus allows the layer to be processed 52 to be etched with high precision.

Thus the first embodiment provides a method of fabricating a semiconductor device, in which the layer to be processed 52 has an upper surface covered with base layer 53, and in that condition, a plurality of intermediate layers deposited on base layer 53 are patterned to provide an intermediate layer pattern having a final pattern.

Thus, while the layer to be processed 52 is protected, photolithography can be performed a plurality of times at overlying layers. This can reduce the number of deposition steps to provide the layer to be processed 52 with a fine pattern by a smaller number of steps than a conventional fabrication process. Furthermore, if chemical vapor deposition is employed to deposit the first and second intermediate layers 54 and 55, there are a large number of selectable materials and a variety of combinations thereof can be used.

The method of fabricating the semiconductor device in the first embodiment is suitable for the double hole system and the double trench system. The double hole system is suitable for a step of forming a contact and a step of forming a via hole. Note that a via-first, dual damascene process requires filling a via. The via is filled by depositing an organic base layer by spin-coating, and as the organic base layer, a 2-layer intermediate layer spreading and thus filling the via well is useful. The double trench system is suitable for a Cu multilayer interconnection process provided by a damascene process forming a groove and providing an interconnect therein.

First Exemplary Variation

In the above description, on an upper surface of the layer to be processed 52, base layer 53 is deposited that is formed of amorphous carbon or a similar inorganic material that can be deposited by chemical vapor deposition. Alternatively, base layer 53 may be deposited that is configured for example of a polymer containing an aromatic ring of a phenyl group, a naphthyl group or the like that can be deposited by spin-coating.

In that case, with reference to FIG. 1, on the upper surface of the layer to be processed 52, a carbon-rich underlying layer material used in a multilayer resist method that is a polymer containing an aromatic ring of a phenyl group, a naphthyl group or the like is deposited by spin-coating to be 100 nm to 300 nm and undergoes a hard bake of approximately 200° C. to 250° C. for one to two minutes.

This provides base layer 53 formed of carbon rich organic film that is a high polymer containing an aromatic compound of a benzene ring, a naphthalene ring or the like, an alicyclic compound of norbornene, adamantyl or the like, or the like, and has a carbon content of at least 75% by weight. (The step of depositing a base layer ends.) Note that the carbon rich organic film having the carbon content of at least 75% by weight ensures etching selectivity for a variety of types of layers to be processed 52. Thus when the layer to be processed 52 is etched, it can be patterned satisfactorily.

Then on an upper surface of base layer 53 an intermediate layer material (a first intermediate layer material) containing a cross linking silsesquioxane derivative and a cross linker as main components is deposited by spin-coating to have a thickness of 50-150 nm and subjected to a hard bake of approximately 200° C. to 250° C. for one to two minutes to undergo a thermosetting process. This provides the first intermediate layer 54 formed of polysilsesquioxane. (The step of depositing a first intermediate layer ends.) Note that polysilsesquioxane is represented by the following chemical formula 1:

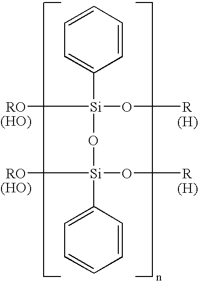

In the formula, R═H, C₂H₆, an inert group or the like. The portion of the phenyl group is a CH₃ group or may be phenyl and methyl mixed together.

Subsequently on an upper surface of the first intermediate layer 54 a solution of a mixture of a cross linking polydiphenylsilane produced by Osaka Gas Chemicals Co., Ltd. and an epoxy cross linker of propylene glycol monomethyl ether is applied as a thermosetting polysilane film (a second intermediate layer material) by spin-coating or the like to have a thickness of 30-70 nm and is subjected to a hard bake of approximately 200° C. for one to two minutes to undergo a thermosetting process. This provides the second intermediate layer 55 formed of polysilane film as represented below by a chemical formula 2. Note that the thermosetting polysilane film can be implemented by those described in Japanese Patent Nos. 3486123 and Japanese Patent Laying-Open No. 2001-093824. (The step of depositing a second intermediate layer ends.)

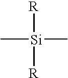

In the formula, R=a phenyl group, a methyl group or a similar, short chain alkyl group.

If the second intermediate layer 55 prevents fully controlling reflectance or causes a chemical reaction to cause a pattern to flare, then, as shown in FIG. 2, anti reflection layer 56 may be deposited on the upper surface of the second intermediate layer 55. Anti reflection layer 56 is deposited by applying a commercially available, first minimum organic ARC produced by Nissan Chemical Industries Ltd. as ARC 83 to have a thickness for example of approximately 40 nm.

On an upper surface of anti reflection layer 56, an ArF photosensitive, chemically amplified resist is applied, and subsequently, a post applied bake (PAB) step of approximately 100° C. is performed to deposit a resist layer.

Over the deposited resist layer, a mask is deposited. This mask (a first mask) is a mask of required circuit patterns that is described in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006), and divided for exposure to light for a double trench structure configured of a space of a minimum width (for example of 32 nm) and a line of a width of 3 times the minimum width (i.e., of 96 nm).

With this mask used, the resist layer is exposed to light. It is then subjected to a post exposure bake (PEB) at approximately 100° C. to 140° C. for approximately one minute, developed for approximately 30 seconds to one minute with a solution of 2.38 wt % of tetra ammonium hydroxide (TMAH), and thereafter baked at approximately 110° C. for approximately one minute to provide resist pattern 57 (a first resist pattern). In doing so, the resist layer may have an upper layer coated with such an on-resist top coating as described in Japanese Patent Laying-Open Nos. 2006-267521 and 2006-227632, as required. (The step of forming a first resist pattern ends.)

Subsequently, as shown in FIG. 3, resist pattern 57 is used as a mask to pattern the second intermediate layer 55 to transfer a pattern of resist pattern 57 to the second intermediate layer 55. The second intermediate layer 55 is etched with a halogen gas of fluorocarbon gas (CF₄, CHF₃, CH₂F₂, CH₃F), chlorine gas (Cl₂), hydrogen bromide HBr) gas. Intermediate layer pattern 55a is thus formed.

When intermediate layer pattern 55a is thus formed, an alignment mark is arranged.

With reference to FIG. 4, an O₂ plasma process is performed to ash away resist pattern 57 and anti reflection layer 56. Wet resist peeling with sulfuric acid and hydrogen peroxide or the like may also be employed together, as required. Intermediate layer pattern 55a is thus externally exposed.

As shown in FIG. 5, for example, a commercially available organic ARC produced by Nissan Chemical Industries, Ltd. as a second minimum organic ARC, i.e., ARC 29, is applied to have a thickness of approximately 80 nm to deposit anti reflection layer 60. While anti reflection layer 60 is thin film, it is introduced into a gap formed between intermediate layer patterns 55a and thus provides a flat surface, and also controls reflectance.

On an upper surface of anti reflection layer 60, an ArF photosensitive, chemically amplified resist is applied, and subsequently, a post applied bake (PAB) step of approximately 100° C. is performed to deposit a resist layer.

Over the deposited resist layer, a mask is deposited, and an exposure step is performed. This mask is a mask of circuit patterns required that is divided for exposure by a projection aligner to light for a double trench structure configured of a space of a minimum width (for example of 32 nm) and a line of a width of 3 times the minimum width (i.e., of 96 nm), such as described in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006).

Thus the resist layer is exposed to light to form resist pattern 61. Resist pattern 61 has gap 161, which overlies intermediate later pattern 55a.

Note that when a mask is used to form resist pattern 61, the resist layer may have an upper layer coated with such an on-resist top coating as described in Japanese Patent Laying-Open Nos. 2006-267521 and 2006-227632, as required. In arranging the mask, it is necessary to arrange the mask, which overlies intermediate layer pattern 55a, to have a positional relationship with intermediate layer pattern 55a at a precision for example of approximately a few nm.

Note that the first intermediate layer 54 configured of a silicon oxide type polysilsesquioxane derivative has an upper surface underlying intermediate layer pattern 55a configured of a polysilicon type polysilane film. Thus when an alignment pattern formed when intermediate layer pattern 55a shown in FIG. 4 is formed is exposed to broadband light to positionally detect an alignment mark with a CCD or a similar imaging device, a high optical contrast of the alignment mark can be obtained. This allows a mask to be registered with high precision to provide a pattern accurately.

Subsequently, as shown in FIG. 6, resist pattern 61 is used to pattern intermediate layer pattern 55a to transfer a pattern of resist pattern 61 to intermediate layer 55 to form intermediate layer pattern 55b. Note that fluorocarbon gas can be obtained from CF₄, CHF₃, CH₂F₂, CH₃F and may be such fluorocarbon gases mixed together.

Note that gap 161 shown in FIG. 5 overlies intermediate layer pattern 55a, and intermediate layer pattern 55b is thus finer than intermediate layer pattern 55a.

Thus a pattern of a fine repeated pitch below “0.25” can be provided to intermediate layer pattern 55b.

As shown in FIG. 7, an O₂ plasma process is performed to ash away resist pattern 61 and anti reflection layer 60a. Wet resist peeling with sulfuric acid and hydrogen peroxide or the like may also be employed together, as required. Intermediate layer pattern 55b is thus externally exposed.

Subsequently, as shown in FIG. 8, intermediate layer pattern 55b is used as a mask to pattern the first intermediate layer 54 and base layer 53 to form the first intermediate layer pattern 54a and base layer pattern 53a. In doing so, the second intermediate layer pattern 55b formed of thermosetting polysilane film spontaneously disappears.

Subsequently, as shown in FIG. 9, the first intermediate layer pattern 54a and base layer pattern 53a thus formed are used as a mask to pattern the layer to be processed 52 to allow the layer to have pattern 52a of a fine repeated pitch with process factor k1 below “0.25”.

The first intermediate layer pattern 54a formed of a polysilsesquioxane derivative spontaneously disappears in patterning the layer to be processed 52. Accordingly, it is not necessary to perform a particular step therefor.

Note that a carbon rich underlying layer material may be deposited on CVDed amorphous carbon. The polysilane film may be replaced with polysilicon. The cross linking silsesquioxane derivative may be replaced with tetraethoxysilane (TEOS) or silicon nitride film or the like forming a multilayer film.

### Second Embodiment

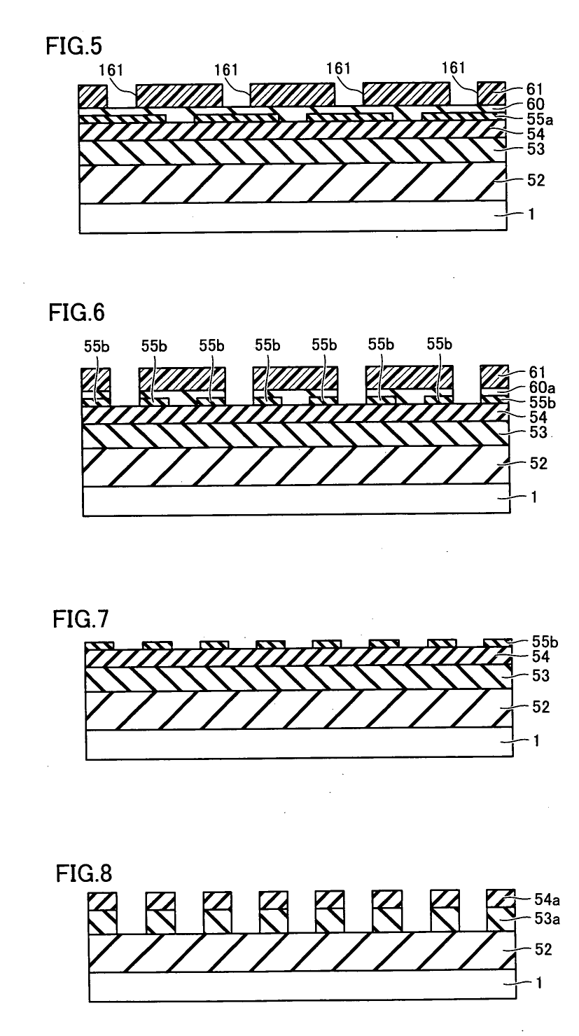

Reference will be made to FIGS. 10-17 to describe a method of fabricating a semiconductor device in a second embodiment. Components that are identical to or correspond to those shown in FIGS. 1-9 are identically denoted and will not be described repeatedly.

FIG. 10 is a cross section for illustrating a first step of the method of fabricating the semiconductor device in the second embodiment. As shown in FIG. 10, on a main surface of semiconductor substrate 1 a layer to be processed 22 is deposited.

On an upper surface of the layer to be processed 22, a carbon-rich underlying layer material of a polymer containing an aromatic ring of a phenyl group, a naphthyl group or the like is deposited by spin-coating to be 100 nm to 300 nm and undergoes a hard bake of approximately 200° C. to 250° C. for one to two minutes to deposit a base layer 23.

Subsequently, on an upper surface of base layer 23, AQUAMICA of AZ Electronic Materials, serving as polysilazane, is applied by spin-coating, and subjected to a hard bake of approximately 250° C. to 300° C. for one to two minutes in a hot plate controlled to have a constant humidity of approximately 35% to undergo a thermosetting process, and burnt to deposit a first intermediate layer 24 formed of a first intermediately layer material of hard SiO₂ and having a thickness of 50-100 nm.

Note that polysilazane reacts with water to become silicon oxide, as indicated by the following expression (2):

—(SiH₂NH)—+2H₂O→SiO₂+NH₃+2H₂ (2).

The humidity can be controlled by sending air to the hot plate from a humidity control system employed for an application cap.

Furthermore in connection with the polysilazane thermosetting process if hard-baking the polysilazane is insufficient to sufficiently provide hard SiO₂ it is effective to process the polysilazane with heated vapor of approximately 200° C. to 450° C. for approximately 10 to 300 seconds to facilitate the polysilazane's setting reaction.

Furthermore, as another means for facilitating the reaction, it is effective to rinse the polysilazane with ultrapure water or a surfactant containing, aqueous solution and subsequently heat the polysilazane at approximately 150° C. to 350° C. for 60 to 3,600 seconds.

Furthermore, as another means for facilitating the reaction, it is effective to rinse the polysilazane with a hydrous organic solvent that does not solve the polysilazane, and subsequently heat the polysilazane at approximately 150° C. to 350° C. for 60 to 3,600 seconds. As the hydrous organic solvent, a hydrous organic solvent having a moisture content of approximately 0.1% to 5% can be selected. For example, a hydrous organic solvent of long chain alcohol, preferably of isopropyl alcohol, iso butanol, and the like can be selected.

Thus employing a hydrous organic solvent having a moisture content of approximately 0.1% to 5% in setting the polysilazane allows water to be provided across the surface of the polysilazane and into an internal portion of the polysilazane and can thus facilitate the polysilazane's setting reaction.

If the hydrous organic solvent has a moisture content smaller than 0.1%, an amount of water that is required to set the polysilazane cannot be obtained. If the hydrous organic solvent has a moisture content larger than 5%, the polysilazane having been set has an increased amount of water remaining therein, and when the set polysilazane is subsequently dried, it may be difficult to sufficiently remove water therefrom, which may result in poor film deposition.

Note that a hydrous organic solvent that does not solve the polysilazane is a hydrous organic solvent that varies the polysilazane that is immersed therein in surface area at a rate of change of at most 5% relative to a surface area that the polysilazane had before it was immersed therein.

Subsequently a solution of a mixture of a cross linking polydiphenylsilane produced by Osaka Gas Chemicals Co., Ltd. and an epoxy cross linker of propylene glycol monomethyl ether is applied as a thermosetting polysilane film to have a thickness of 30-70 nm and subjected to a hard bake of approximately 200° C. for one to two minutes to undergo a thermosetting process to deposit a second intermediate layer 25. The thermosetting polysilane film can be implemented by those described in Japanese Patent Nos. 3486123 and Japanese Patent Laying-Open No. 2001-093824.

FIG. 11 is a cross section for illustrating a second step of the process for fabricating the semiconductor device in the second embodiment. In FIG. 11, if the second intermediate layer 25 prevents fully controlling reflectance or causes a chemical reaction to cause a pattern to flare, then, a commercially available, first minimum organic ARC produced by Nissan Chemical Industries Ltd. as ARC 83 may be applied thereon to have a thickness of approximately 40 nm to deposit an anti reflection layer 26.

Thereon a resist is applied. More specifically, an ArF photosensitive, chemically amplified resist is applied, and subsequently, a post applied bake (PAB) step of approximately 100° C. is performed. Subsequently a projection aligner is employed to expose the resist to light with a first mask of circuit patterns required that is divided for exposure to light for a double line structure configured of a line of a minimum width (for example of 32 nm) and a space of a width of 3 times the minimum width (i.e., of 96 nm), such as described in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006).

The resist is subjected to a post exposure bake (PEB) of approximately 100° C. to 140° C. for approximately one minute, developed for approximately 30 seconds to one minute with a solution of 2.38 wt % of tetra ammonium hydroxide (TMAH), and thereafter baked at approximately 110° C. for approximately one minute to provide a resist pattern 27. In doing so, the resist layer may have an upper layer coated with such an on-resist top coating as described in Japanese Patent Laying-Open Nos. 2006-267521 and 2006-227632, as required.

FIG. 12 is a cross section for illustrating a third step of the process for fabricating the semiconductor device in the second embodiment. As shown in FIG. 12, resist pattern 27 is used as a mask to etch the second intermediate layer 25 to transfer a resist pattern to the second intermediate layer 25. The layer is etched with fluorocarbon gas of CF₄, CHF₃, CH₂F₂, CH₃F or may be etched with such fluorocarbon gases mixed together. A second intermediate layer pattern 25a is thus formed.

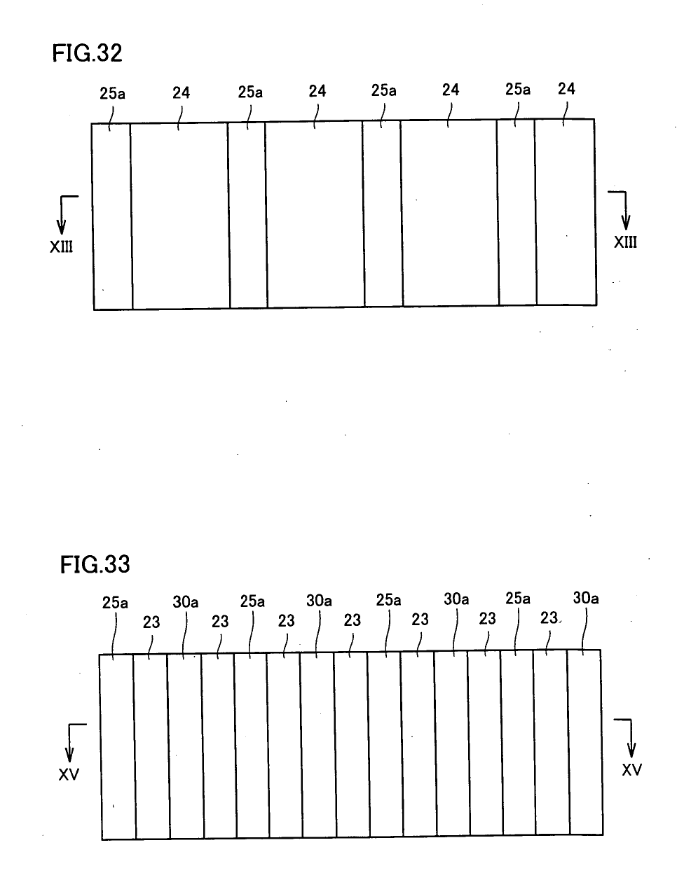

FIG. 13 is a cross section for illustrating a fourth step of the process for fabricating the semiconductor device in the second embodiment. FIG. 32 is a plan view in the fourth step. As shown in FIGS. 13 and 32, an O₂ plasma process is performed to ash away resist pattern 27 and anti reflection layer 26. Wet resist peeling with sulfuric acid and hydrogen peroxide or the like may also be employed together, as required. The second intermediate layer pattern 25a is thus externally exposed.

FIG. 14 is a cross section for illustrating a fifth step of the process for fabricating the semiconductor device in the second embodiment. As shown in FIG. 14, a commercially available organic ARC produced by Nissan Chemical Industries, Ltd. as a second minimum organic ARC, i.e., ARC 29, is applied to have a thickness of approximately 110 nm to deposit an anti reflection layer 30. While anti reflection layer 30 is thin film, it can be introduced into a gap formed between the second intermediate layer patterns 25a and thus provide a flat surface, and also control reflectance.

On anti reflection layer 30, an ArF photosensitive, chemically amplified resist is applied, and subsequently, a post applied bake (PAB) step of approximately 100° C. is performed to deposit a resist layer.

Subsequently, of circuit patterns required, a mask (a third mask) that is divided for exposure to light for a double line structure configured of a line of a minimum width (for example of 32 nm) and a space of a width of 3 times the minimum width (i.e., of 96 nm), such as described in Chang-Moon Lim, Seo-Min Kim, Young-Sun Hwang et al., “Positive and Negative Tone Double Patterning Lithography for 50 nm Flash Memory” Proc. of SPIE vol. 6154, 615410-P1-8 (2006), is used to expose the resist layer to light.

The resist is then subjected to a post exposure bake (PEB) at approximately 100° C. to 140° C. for approximately one minute, developed for approximately 30 seconds to one minute with a solution of 2.38 wt % of tetra ammonium hydroxide (TMAH), and thereafter baked at approximately 110° C. for approximately one minute to provide a resist pattern 31.

In doing so, the resist layer may have an upper layer coated with such an on-resist top coating as described in Japanese Patent Laying-Open Nos. 2006-267521 and 2006-227632, as required.

Resist pattern 31 overlies a gap 125 of the second intermediate layer pattern 25a. In other words, it overlies intermediate layer 24 located adjacent to gap 125 of the second intermediate layer pattern 25a.

FIG. 15 is a cross section for illustrating a sixth step of the process for fabricating the semiconductor device in the second embodiment. FIG. 33 is a plan view in the sixth step. As shown in FIGS. 15 and 33, resist pattern 31 and the second intermediate layer pattern 25a are used as a mask to pattern the first intermediate layer 24 formed of hard SiO₂ film produced by burning polysilazane. A first intermediate layer pattern 24a is thus formed.

The patterning can be done with fluorocarbon gas including CF₄, CHF₃, CH₂F₂ and CH₃F, and may be done with a mixture of these fluorocarbon gases, or such fluorocarbon gas with oxygen, nitrogen or the like added thereto and thus mixed together.

Thus patterning the first intermediate layer 24 forms the first intermediate layer pattern 24a that has an interval smaller than that of the second intermediate layer pattern 25a and for example has a pattern of a fine repeated pitch below “0.25”.

Note that the first intermediate layer pattern 24a having an upper surface with an anti reflection layer 30a deposited thereon and the first intermediate layer pattern 24a having an upper surface with the second intermediate layer pattern 25a deposited thereon are alternately arranged.

FIG. 16 is a cross section for illustrating a seventh step of the process for fabricating the semiconductor device in the second embodiment. In FIG. 16, with the second intermediate layer pattern 25a and anti reflection layer 30a remaining on the upper surface of the first intermediate layer pattern 24a, as shown in FIG. 15, base layer 23 is patterned to form a base layer pattern 23a.

Thus, as shown in FIG. 16, base layer pattern 23a of a fine pitch is formed. On an upper surface of base layer pattern 23a, what is formed of the first intermediate layer pattern 24a and the second intermediate layer pattern 25a, and the first intermediate layer pattern 24a alone are alternately provided.

The layer to be processed 22, required for a device structure, which must finally be processed, can be etched with the carbon rich base layer pattern 23a used as a mask such that the layer to be processed 22 is implemented by a variety of types of film. Furthermore, the first intermediate layer pattern 24a configured of polysilazane film and the second intermediate layer pattern 25a formed of polysilane film spontaneously disappear in etching the layer to be processed 22. Accordingly, no particular removal step is required. The method of fabricating the semiconductor device in the second embodiment (or a double line system) is suitable for a step of forming a gate, that forms a left interconnect.

First Exemplary Variation

In the second embodiment the first intermediate layer 24 is formed of polysilazane film and the second intermediate layer 25 is formed of polysilane film. However, the layers are not limited to such films.

For example, the first intermediate layer 24 may be formed of polysilane film and the second intermediate layer 25 may be formed of polysilazane film.

Hard SiO₂ obtained by thermosetting polysilazane has a larger etching selectivity than polysilane, polysilsesquioxane or a similar material containing Si_{X}O_{Y}C_{Z}, the element of hydrogen and an unavoidably contained element, wherein X, Y and Z are any integers. Accordingly, one of the first intermediate layer 24 and the second intermediate layer 25 is formed of hard SiO₂ obtained by thermosetting polysilazane, and the other is formed of polysilane, polysilsesquioxane or a similar material containing Si_{X}O_{Y}C_{Z}, the element of hydrogen and an unavoidably contained element, wherein X, Y and Z are any integers. For example, if an etchant gas based on hydrogen bromide (HBr) gas is used, then, with reference to polysilsesquioxane, hard SiO₂ obtained by thermosetting polysilazane provides an etching selectivity of approximately 0.1231 and polysilane provides an etching selectivity of approximately 1.005. Furthermore if an etchant gas of C₄F₈/argon gas is used, then, with reference to polysilsesquioxane, hard SiO₂ obtained by thermosetting polysilazane provides an etching selectivity of approximately 9.1532 and polysilane provides an etching selectivity of approximately 0.232. Hard SiO₂ obtained by thermosetting polysilazane can thus ensure a large etching selectivity of at least 3 relative to polysilane, polysilsesquioxane or a similar material containing Si_{X}O_{Y}C_{Z}, the element of hydrogen and an unavoidably contained element, wherein X, Y and Z are any integers.

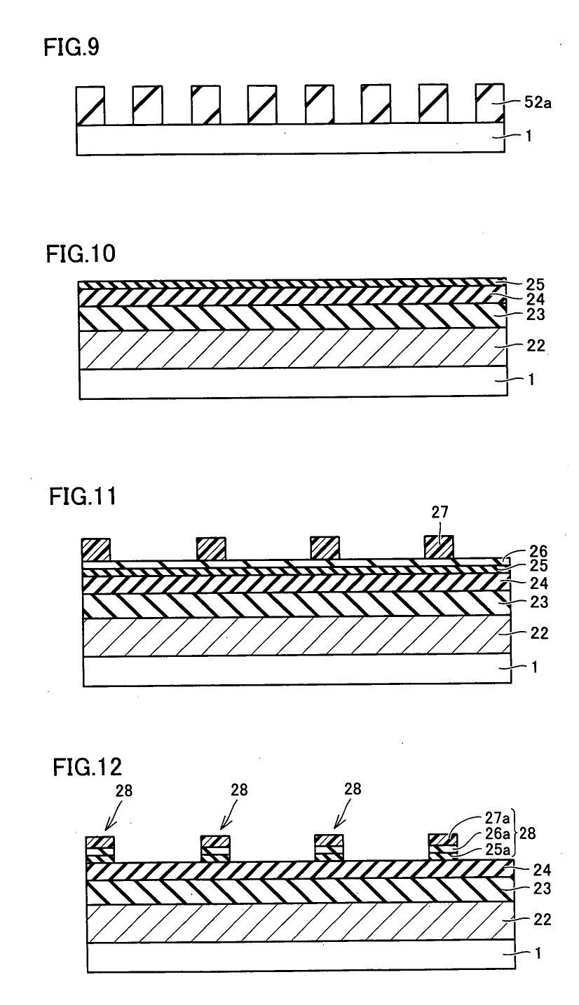

FIG. 17 is a cross section for illustrating a step performed after the process for fabricating the semiconductor device as shown in FIG. 15. In FIG. 17, before base layer 23 is patterned, only anti reflection layer 30a and the second intermediate layer pattern 25a formed of polysilazane film shown in FIG. 15 are selectively removed by dry removal employing diluted hydrofluoric acid, fluorocarbon gas or the like, and the first intermediate layer pattern 24a formed of polysilane film is externally exposed.

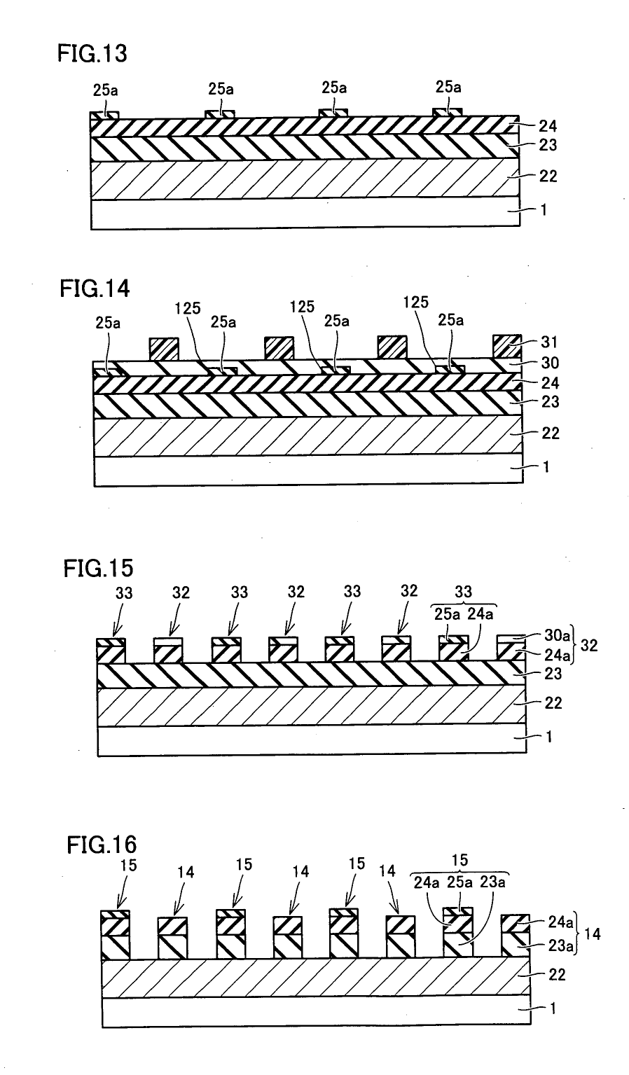

FIG. 18 is a cross section for illustrating a step performed after that shown in FIG. 17. As shown in FIG. 18, with the first intermediate layer pattern 24a alone remaining, base layer 23 is patterned to form base layer pattern 23a. Base layer 23 is formed of organic film, and if a defect arises, a reproduction process can be performed to reproduce base layer 23 by a simple process.

Second Exemplary Variation

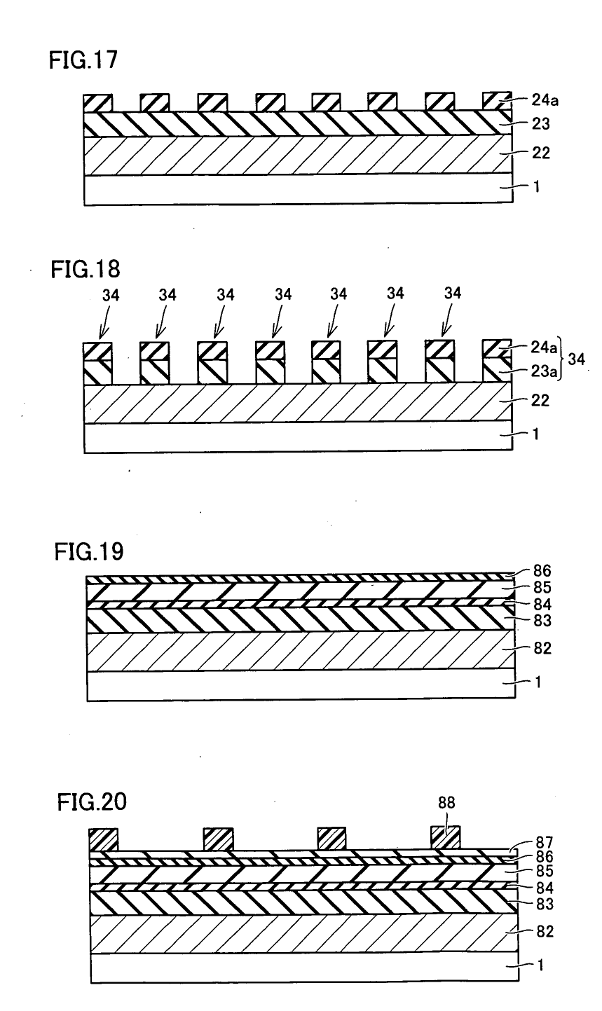

Reference will be made to FIGS. 19-27 to describe a second exemplary variation of the semiconductor device in the second embodiment.

FIG. 19 is a cross section for illustrating a first step of a process for fabricating a semiconductor device in the second exemplary variation. As shown in FIG. 19, on a main surface of semiconductor substrate 1, a layer to be processed 82 is deposited, and on an upper surface of the layer to be processed 82, a base layer 83 formed of a carbon rich underlying layer material, a first intermediate layer 84 formed of polysilazane, and a second intermediate layer 85 formed of polysilane film are deposited, similarly as described for the step shown in FIG. 10.

Furthermore, on the second intermediate layer 85, a third intermediate layer 86 deposited similarly as the first intermediate layer 84 is done is deposited.

More specifically, on an upper surface of the second intermediate layer 85, AQUAMICA of AZ Electronic Materials, serving as polysilazane, is applied by spin-coating, and subjected to a hard bake of approximately 250° C. to 300° C. for one to two minutes in a hot plate controlled to have a constant humidity of approximately 35% to undergo a thermosetting process, and burnt to deposit the third intermediate layer 86 formed of a first intermediate layer material of hard SiO₂ and having a thickness of 50-100 nm.

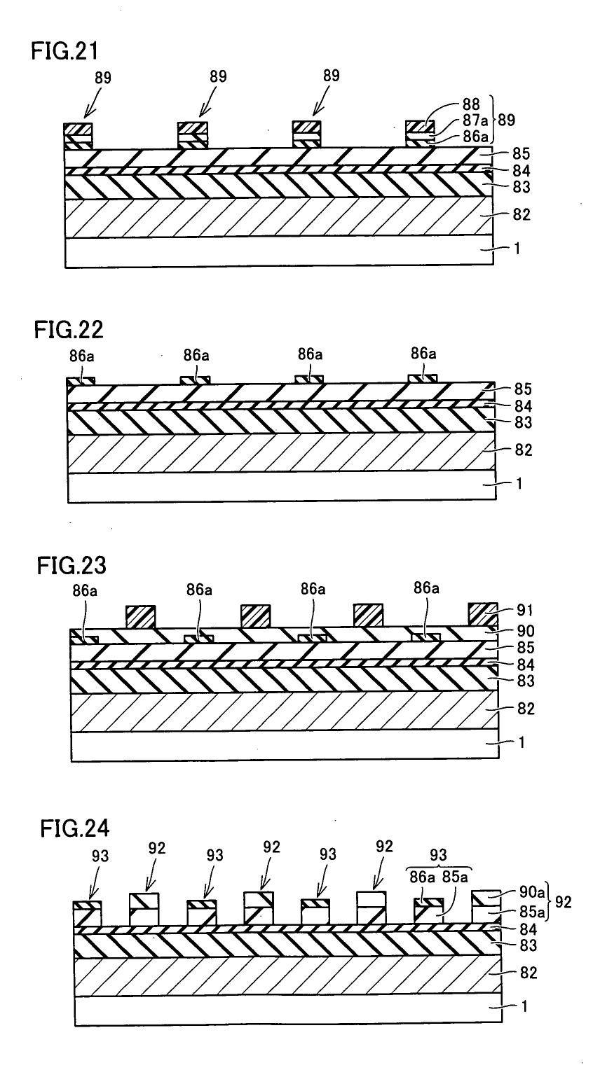

FIG. 20 is a cross section for illustrating a step performed after the fabrication process shown in FIG. 19. As shown in FIG. 20, an anti reflection layer 87 is deposited and on an upper surface thereof a resist layer is deposited.

Then on the resist layer a mask is deposited. This mask is divided for exposure to light for a double line structure configured of a line of a minimum width (for example of 32 nm) and a space of a width of 3 times the minimum width (i.e., of 96 nm), such as described in Chang-Moon Lim, Seo-Min Kim, Young-Sun Hwang et al., “Positive and Negative Tone Double Patterning Lithography for 50 nm Flash Memory” Proc. of SPIE vol. 6154, 6154100—P1-8 (2006).

With this mask used, the resist layer is exposed to light to form a resist pattern 88.

FIG. 21 is a cross section for illustrating a step performed after the fabrication process shown in FIG. 20. As shown in FIG. 21, resist pattern 88 is used as a mask to pattern the third intermediate layer 86 to form a third intermediate layer pattern 86a.

FIG. 22 is a cross section for illustrating a step performed after the fabrication process shown in FIG. 21. As shown in FIG. 22, resist pattern 88 and anti reflection layer 87a are removed. The third intermediate layer pattern 86a is thus externally exposed.

FIG. 23 is a cross section for illustrating a step performed after the fabrication process shown in FIG. 22. As shown in FIG. 23, an anti reflection layer 90 is deposited on the third intermediate layer pattern 86a. This can fill a gap between the third intermediate layer patterns 86a. Note that an etching selectivity of the second intermediate layer 85 relative to the third intermediate layer 86 and that of the third intermediate layer 86 relative to the second intermediate layer 85 are both set for example at least 2. This allows the third intermediate layer 86 to be a thin film. Thus when anti reflection layer 90 is deposited on the third intermediate layer pattern 86a, anti reflection layer 90 can be prevented from having a significantly inclined portion, and on an upper surface of anti reflection layer 90a resist layer can be deposited to have a generally flat plane.

Then on the resist layer a mask is deposited and the resist layer is exposed to light to form a resist pattern 91. Resist pattern 91 overlies a gap of the third intermediate layer pattern 86a.

FIG. 24 is a cross section for illustrating a step performed after the fabrication process shown in FIG. 23. As shown in FIG. 24, resist pattern 91 and the third intermediate layer pattern 86a shown in FIG. 23 are used as a mask to pattern the second intermediate layer 85.

Thus patterning the second intermediate layer 85 transfers a pattern of the third intermediate layer pattern 86a and that of resist pattern 91 to form a second intermediate layer pattern 85a having a fine pattern.

The second intermediate layer pattern 85a has alternately arranged a pattern having an upper surface with anti reflection layer 90a deposited thereon and a pattern having an upper surface with the third intermediate layer pattern 86a deposited thereon. The first intermediate layer 84 serves as a film protecting base layer 83.

FIG. 25 is a cross section for illustrating a step performed after the fabrication process shown in FIG. 24. As shown in FIG. 25, the second intermediate layer pattern 85a is used as a mask to pattern the first intermediate layer 84 to form a first intermediate layer pattern 84a. In doing so, base layer 83 serves as a film protecting the layer to be processed 82.

FIG. 26 is a cross section for illustrating a step performed after the fabrication process shown in FIG. 25. With reference to FIG. 26, the first intermediate layer pattern 84a is used as a mask to pattern base layer 83 to form a base layer pattern 83a.

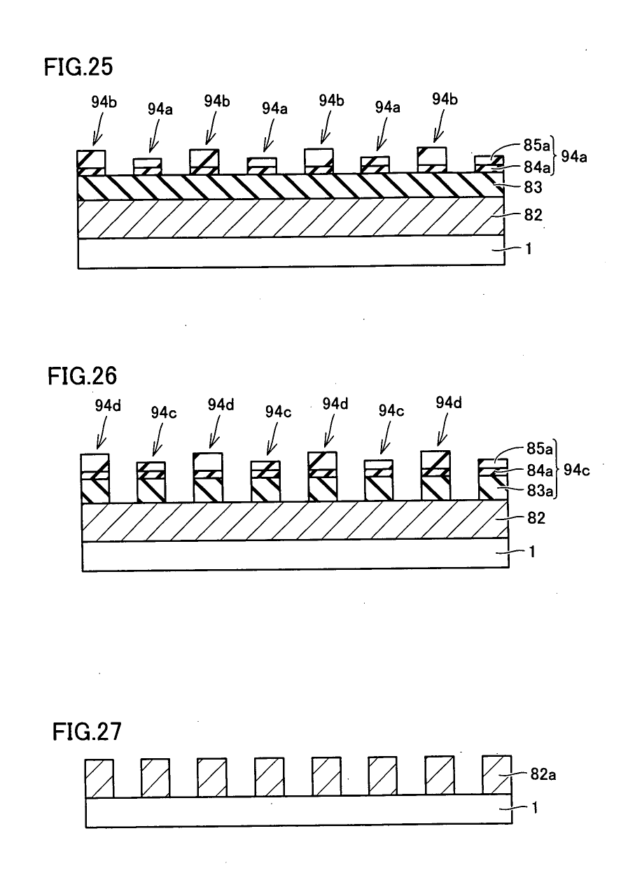

FIG. 27 is a cross section for illustrating a step performed after that shown in FIG. 26. As shown in FIG. 27, base layer pattern 83a can be used as a mask to pattern the layer to be processed 82 to obtain a fine pattern 82a for example of a gate.

Thus on base layer 83 a stack of intermediate layers may be patterned to have a pattern, and the stack of intermediate layers thus patterned may be used to pattern the base layer to provide the base layer with a pattern, and a layer to be processed may thus be patterned to obtain a fine pattern. The method of fabricating a semiconductor device as described in the first and second embodiments can be applied to a separation step, a step of forming a gate, a step of forming a contact, a step of forming an interconnect and a step of forming a via hole in that order to fabricate a semiconductor device including a fine pattern.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of fabricating a semiconductor device, comprising the steps of:
depositing on a main surface of a semiconductor substrate a layer to be processed;
depositing a base layer on said layer to be processed;
depositing a first intermediate layer and then a second intermediate layer on said base layer;
patterning said second intermediate layer while said base layer covers said layer to be processed;
depositing a first mask pattern on said second intermediate layer patterned;
patterning said second intermediate layer with said first mask pattern;
patterning said first intermediate layer and said base layer with said second intermediate layer patterned, to form a second mask pattern; and
patterning said layer to be processed, with said second mask pattern.

2. The method of fabricating a semiconductor device according to claim 1, wherein an etching selectivity of said second intermediate layer relative to said first intermediate layer with reference to said first intermediate layer and an etching selectivity of said first intermediate layer relative to said second intermediate layer with reference to said second intermediate layer are smaller than an etching selectivity of said layer to be processed relative to said base layer with reference to said base layer.

3. The method of fabricating a semiconductor device according to claim 1, wherein said first intermediate layer is a silicon oxide layer and said second intermediate layer is a polysilane layer.

4. The method of fabricating a semiconductor device according to claim 1, wherein said first intermediate layer is one of a polysilsesquioxane derivative layer and a polysilazane layer.

5. The method of fabricating a semiconductor device according to claim 1, wherein said first intermediate layer is a polysilane layer and said second intermediate layer is a polysilazane layer.

6. The method of fabricating a semiconductor device according to claim 1, wherein said first and second intermediate layers are formed of a material for film that can be deposited by chemical vapor deposition.

7. The method of fabricating a semiconductor device according to claim 1, wherein said first and second intermediate layers are formed of a material for film that can be deposited by spin coating.

8. The method of fabricating a semiconductor device according to claim 1, wherein said base layer is an organic layer.

9. The method of fabricating a semiconductor device according to claim 8, wherein said organic layer has a carbon content of at least 75% by weight.

10. The method of fabricating a semiconductor device according to claim 1, wherein said base layer is formed of an inorganic material that can be deposited by chemical vapor deposition.

11. The method of fabricating a semiconductor device according to claim 10, wherein said base layer is amorphous carbon.

12. The method of fabricating a semiconductor device according to claim 1, wherein the step of depositing said first and second intermediate layers includes the step of depositing a polysilazane layer as one of said first and second intermediate layers.

13. The method of fabricating a semiconductor device according to claim 1, wherein: one of said first and second intermediate layers is a polysilazane layer; and the other of said first and second intermediate layers has an etching selectivity of at least three relative to any of said base layer and said polysilazane layer, and vise versa.

14. The method of fabricating a semiconductor device according to claim 1, wherein one of said first and second intermediate layers is a polysilazane layer and the other of said first and second intermediate layers is one of a polysilane layer and a polysilsesquioxane layer.

15. The method of fabricating a semiconductor device according to claim 12, further comprising the step of applying heated vapor to cause said polysilazane layer's setting reaction to proceed.

16. The method of fabricating a semiconductor device according to claim 12, further comprising the steps of: rinsing said polysilazane layer with one of pure water and a surfactant containing aqueous solution; and heating said polysilazane layer to cause said polysilazane layer's setting reaction to proceed.

17. The method of fabricating a semiconductor device according to claim 12, further comprising the steps of: rinsing said polysilazane layer with a hydrous organic solvent that does not solve said polysilazane layer; and heating said polysilazane layer to cause said polysilazane layer's setting reaction to proceed, wherein said hydrous organic solvent has a moisture content ranging from 0.1% to 5%.

18. A method of fabricating a semiconductor device, comprising the steps of:
depositing on a main surface of a semiconductor substrate a layer to be processed;
depositing a base layer on an upper surface of said layer to be processed;
depositing a plurality of intermediate layers stacked on an upper surface of said base layer;
patterning said intermediate layers more than once to form a stack of patterned layers; and
etching said base layer and said layer to be processed, with said stack of patterned layers used as a mask.

19. A method of fabricating a semiconductor device, comprising the steps of:
depositing on a main surface of a semiconductor substrate a layer to be processed;
depositing a base layer on said layer to be processed;
depositing a first intermediate layer and then a second intermediate layer on said base layer;
patterning said second intermediate layer while said base layer covers said layer to be processed;
depositing a first mask pattern on said first intermediate layer located adjacent to a gap of said second intermediate layer patterned;
patterning said first intermediate layer with said first mask pattern and said second intermediate layer patterned;
patterning said base layer with said first intermediate layer patterned, to form a second mask pattern; and
patterning said layer to be processed, with said second mask pattern.

20. The method of fabricating a semiconductor device according to claim 19, wherein an etching selectivity of said second intermediate layer relative to said first intermediate layer with reference to said first intermediate layer and an etching selectivity of said first intermediate layer relative to said second intermediate layer with reference to said second intermediate layer are smaller than an etching selectivity of said layer to be processed relative to said base layer with reference to said base layer.

21. The method of fabricating a semiconductor device according to claim 19, wherein said first intermediate layer is a silicon oxide layer and said second intermediate layer is a polysilane layer.

22. The method of fabricating a semiconductor device according to claim 19, wherein said first intermediate layer is one of a polysilsesquioxane derivative layer and a polysilazane layer.

23. The method of fabricating a semiconductor device according to claim 19, wherein said first intermediate layer is a polysilane layer and said second intermediate layer is a polysilazane layer.

24. The method of fabricating a semiconductor device according to claim 19, wherein said first and second intermediate layers are formed of a material for film that can be deposited by chemical vapor deposition.

25. The method of fabricating a semiconductor device according to claim 19, wherein said first and second intermediate layers are formed of a material for film that can be deposited by spin coating.

26. The method of fabricating a semiconductor device according to claim 19, wherein said base layer is an organic layer.

27. The method of fabricating a semiconductor device according to claim 26, wherein said organic layer has a carbon content of at least 75% by weight.

28. The method of fabricating a semiconductor device according to claim 19, wherein said base layer is formed of an inorganic material that can be deposited by chemical vapor deposition.

29. The method of fabricating a semiconductor device according to claim 28, wherein said base layer is amorphous carbon.

30. The method of fabricating a semiconductor device according to claim 19, wherein the step of depositing said first and second intermediate layers includes the step of depositing a polysilazane layer as one of said first and second intermediate layers.

31. The method of fabricating a semiconductor device according to claim 19, wherein: one of said first and second intermediate layers is a polysilazane layer; and the other of said first and second intermediate layers has an etching selectivity of at least three relative to any of said base layer and said polysilazane layer, and vise versa.

32. The method of fabricating a semiconductor device according to claim 19, wherein one of said first and second intermediate layers is a polysilazane layer and the other of said first and second intermediate layers is one of a polysilane layer and a polysilsesquioxane layer.

33. The method of fabricating a semiconductor device according to claim 30, further comprising the step of applying heated vapor to cause said polysilazane layer's setting reaction to proceed.

34. The method of fabricating a semiconductor device according to claim 30, further comprising the steps of: rinsing said polysilazane layer with one of pure water and a surfactant containing aqueous solution; and heating said polysilazane layer to cause said polysilazane layer's setting reaction to proceed.

35. The method of fabricating a semiconductor device according to claim 30, further comprising the steps of: rinsing said polysilazane layer with a hydrous organic solvent that does not solve said polysilazane layer; and heating said polysilazane layer to cause said polysilazane layer's setting reaction to proceed, wherein said hydrous organic solvent has a moisture content ranging from 0.1% to 5%.
